(19) United States
(12) Patent Application Publication
(10) Pub. No.: US 2023/0198498 A1
(43) Pub. Date: Jun. 22, 2023

(54) THIN-FILM BULK ACOUSTIC WAVE RESONATOR, FORMING METHOD, AND FILTER

(71) Applicant: Ningbo Semiconductor International Corporation, Ningbo (CN)

(72) Inventors: Wei LI, Ningbo (CN); Herb He HUANG, Ningbo (CN); Hailong LUO, Ningbo (CN)

(21) Appl. No.: 18/109,915

(22) Filed: Feb. 15, 2023

Related U.S. Application Data
(63) Continuation of application No. PCT/CN2021/127858, filed on Nov. 1, 2021.

(30) Foreign Application Priority Data
Nov. 16, 2020 (CN) 202011280289.9

(51) Int. Cl. H03H 9/17; H03H 9/02; H03H 9/13

(52) U.S. Cl. CPC H03H 9/172; H03H 9/02023; H03H 9/02118; H03H 9/132

(57) ABSTRACT

Thin-film bulk acoustic resonator, forming method and filter are provided. The thin-film bulk acoustic resonator includes: a first substrate, an upper surface of the first substrate being provided with a first cavity; a piezoelectric stack structure, disposed on the upper surface of the first substrate and covering the first cavity, the piezoelectric stack structure including a second electrode, a piezoelectric layer and a first electrode which are sequentially stack from bottom to top; a groove, including a first groove and/or a second groove, the first groove penetrating through the first electrode and extending into or penetrating through the piezoelectric layer, the second groove penetrating the second electrode and extending into or penetrating through the piezoelectric layer; and a reinforcement layer, disposed on at least one side of the first electrode or the second electrode at a bottom of the groove.

### CROSS-REFERENCE TO RELATED APPLICATION

This application is a continuation application of PCT Patent Application No. PCT/CN2021/127858, filed on Nov. 1, 2021, which claims priority to Chinese patent application No. 202011280289.9, filed on Nov. 16, 2020, the entire contents of all of which is incorporated by reference.

### FIELD OF THE DISCLOSURE

The present disclosure generally relates to the field of semiconductor device manufacturing and, more particularly, relates to a thin-film bulk acoustic wave resonator, a forming method, and a filter.

### BACKGROUND

With continuous development of the wireless communication technology, to meet multi-functional requirements of various wireless communication terminals, a terminal device needs to be able to transmit data using different carrier frequency spectrums. At a same time, to support a sufficient data transmission rate within a limited bandwidth, strict performance requirements are also put forward for a radio frequency system. A radio frequency filter is an important part of the radio frequency system, which can filter out interferences and noises outside a communication spectrum to meet requirements of the radio frequency system and a communication protocol for a signal-to-noise ratio. Taking a mobile phone as an example, since each frequency band needs a corresponding filter, dozens of filters may need to be set in a mobile phone.

Generally, a thin-film bulk acoustic resonator includes two thin-film electrodes, and a piezoelectric thin-film layer is disposed between the two thin-film electrodes. A working principle of the thin-film bulk acoustic resonator is to use a piezoelectric film layer to generate a vibration under an alternating electric field. The vibration excites a bulk acoustic wave propagating along a thickness direction of the piezoelectric thin-film layer. The acoustic wave is transmitted to an interface between upper and lower electrodes and the air is reflected, and then reflected back and forth inside a film to form an oscillation. Standing wave oscillations are formed when the acoustic wave propagates in the piezoelectric film layer at exactly an odd multiple of half-wavelengths.

However, a cavity-type thin-film bulk acoustic wave resonator produced at present have problems such as transverse wave loss and insufficient structural strength, so that quality factor (Q) cannot be further improved, and yield is low. Therefore, the cavity-type thin-film bulk acoustic wave resonators cannot meet needs of high-performance radio frequency systems.

### BRIEF SUMMARY OF THE DISCLOSURE

One aspect of the present disclosure provides a thin-film bulk acoustic wave resonator. The thin-film bulk acoustic resonator includes: a first substrate, an upper surface of the first substrate being provided with a first cavity; a piezoelectric stack structure, disposed on the upper surface of the first substrate and covering the first cavity, the piezoelectric stack structure including a second electrode, a piezoelectric layer and a first layer which are sequentially stack from bottom to top; a groove, including a first groove and/or a second groove, the first groove penetrating the first electrode and extending into or penetrating through the piezoelectric layer, and the second groove penetrating the second electrode and extending into or penetrating through the piezoelectric layer; and a reinforcement layer, disposed on at least one side of the first electrode or the second electrode at a bottom of the groove.

Another aspect of the present disclosure provides a filter. The filter includes a thin-film bulk acoustic wave resonator. The thin-film bulk acoustic resonator includes: a first substrate, an upper surface of the first substrate being provided with a first cavity; a piezoelectric stack structure, disposed on the upper surface of the first substrate and covering the first cavity, the piezoelectric stack structure including a second electrode, a piezoelectric layer and a first electrode which are sequentially stack from bottom to top; a groove, including a first groove and/or a second groove, the first groove penetrating the first electrode and extending into or penetrating through the piezoelectric layer, and the second groove penetrating the second electrode and extending into or penetrating through the piezoelectric layer; and a reinforcement layer, disposed on at least one side of the first electrode or the second electrode at a bottom of the groove.

Another aspect of the present disclosure provides a method of forming a thin-film bulk acoustic wave resonator. The method includes providing a carrier substrate; forming sequentially a first electrode, a piezoelectric layer and a second electrode are on the carrier substrate; forming a first substrate with a first cavity on the second electrode; and removing the carrier substrate. The thin film bulk acoustic wave resonator includes a second groove and a second reinforcement layer, and forming the second groove and the second reinforcement layer includes: before forming the first electrode, forming the second reinforcement layer on the carrier substrate; after forming the second electrode, forming the second groove penetrating through the second electrode over a region of the second reinforcement layer, and extending into or through the piezoelectric layer. And/or the thin-film bulk acoustic wave resonator includes a first groove and a first reinforcement layer, and forming the first groove and the first reinforcement layer includes: after forming the second electrode, forming the first reinforcement layer on the second electrode; after removing the carrier substrate, forming the first groove penetrating through the first electrode over a region of the first reinforcement layer, and extending into or penetrating through the piezoelectric layer.

Other aspects of the present disclosure can be understood by a person skilled in the art in light of the description, the claims, and the drawings of the present disclosure.

### BRIEF DESCRIPTION OF THE DRAWINGS

The above and other objects, features and advantages of the present disclosure will become more obvious from more detailed descriptions of exemplary embodiments of the present disclosure in conjunction with accompanying drawings. In the exemplary embodiments of the present disclosure, same reference numerals generally refer to same parts.

FIG. 1 illustrates a schematic diagram of an exemplary thin film bulk acoustic wave resonator according to some embodiments of present disclosure.

FIG. 2 illustrates a schematic diagram of another exemplary thin film bulk acoustic wave resonator according to some embodiments of present disclosure. FIGS. 3-9 illustrate schematic diagrams of structures corresponding to certain stages during formation of a thin-film bulk acoustic resonator according to some embodiments of present disclosure. FIGS. 10-16 illustrates schematic diagrams of structures corresponding to certain stages during formation of another thin-film bulk acoustic resonator according to some embodiments of present disclosure.

Reference numeral list: 100—carrier substrate; 101—second dielectric layer; 102—second reinforcement layer; 200—first cavity; 201—first electrode; 202—piezoelectric layer; 203—second electrode; 204—first reinforcement layer; 205—support layer; 206—sacrificial layer; 207—dielectric layer; 208—substrate; 110—second cavity; 40—second groove; 41—first groove; 1021—first protrusion; 2041—second protrusion; and 300—base.

### DETAILED DESCRIPTION

The present disclosure will be further described in detail below with reference to the accompanying drawings and specific embodiments. Advantages and features of the present disclosure will become more obvious from the following descriptions and accompanying drawings. However, it should be noted that concepts of technical solutions of the present disclosure can be implemented in various forms and is not limited to the specific embodiments set forth herein. The accompanying drawings are all in very simplified forms and use inaccurate scales and are used for the purpose of convenience and clarity only to aid in describing the embodiments of the present disclosure.

It will be understood that when an element or layer is referred to as being “on . . . ”, “adjacent to . . . ,” “connected to” or “coupled to” other elements or layers, the element or layer can be directly on, adjacent to, connected to or coupled to the other element or layer or intervening elements or layers may be present. In contrast, when an element is referred to as being “directly on . . . ”, “directly adjacent to . . . ”, “directly connected to” or “directly coupled to” other element or layer, there are no intervening elements or layers present. It will be understood that, although the terms first, second, third, etc. may be used to describe various elements, components, regions, layers and/or sections, the elements, components, regions, layers and/or sections should not be limited by the terms. The terms are only used to distinguish one element, component, region, layer or section from another element, component, region, layer or section. Thus, a first element, component, region, layer, or section discussed below could be termed a second element, component, region, layer or section without departing from the teachings of the present disclosure.

Spatial relationship terms such as “under . . . ”, “below . . . ”, “underneath . . . ”, “beneath . . . ”, “above . . . ”, “over . . . ”, and the like, may be used herein for ease of description to describe a relationship of one element or feature to another element or feature as illustrated in the drawings. It will be understood that the spatially relative terms are intended to encompass different orientations of the device in use or operation in addition to the orientation depicted in the figures. For example, if a device in the drawings is turned over, then elements or features described as “below” or “beneath” other elements or features would then be oriented “above” the other elements or features. Therefore, the exemplary terms “below . . . ” and “under . . . ” can encompass two orientations of up and down. The device may be otherwise oriented (rotated 90 degrees or at other orientations) and the spatial descriptors used herein interpreted accordingly.

The terminology used herein is for the purpose of describing embodiments only and is not intended to be limiting of the invention. As used herein, the singular forms “a”, “an” and “the” are intended to include plural forms as well, unless the context clearly indicates otherwise. It will be further understood that the terms “comprises” and/or “comprising,” when used in the specification, specify a presence of stated features, integers, steps, operations, elements, and/or components, but do not preclude a presence or an addition of one or more other features, integers, steps, operations, elements, components, and/or groups thereof. As used herein, the term “and/or” includes any and all combinations of associated listed items.

If methods herein include a series of steps, an order of the steps presented herein is not necessarily an only order in which the steps can be performed, and some steps may be omitted and/or some other steps not described herein may be added to the method. If components in a certain drawing are same as components in other accompanying drawings, although the components can be easily identified in all the accompanying drawings, to make a description of the accompanying drawings clearer, the present specification will not label all the same components with reference numerals in every drawing.

### Exemplary Embodiment 1

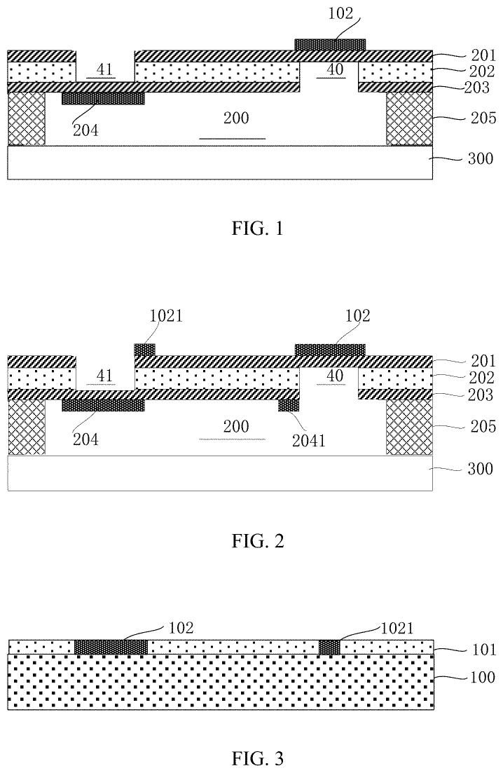

The present embodiment provides a thin film bulk acoustic wave resonator. FIG. 1 illustrates a schematic diagram of a thin-film piezoelectric acoustic resonator provided by exemplary Embodiment 1. Referring to FIG. 1, the thin-film bulk acoustic resonator includes: a first substrate, an upper surface of the first substrate being provided with a first cavity 200; a piezoelectric stack structure, disposed on the upper surface of the first substrate and covering the first cavity 200, the piezoelectric stack structure including a second electrode 203, a piezoelectric layer 202 and a first electrode which are sequentially stack from bottom to top; a groove, including a first groove and/or a second groove, the first groove penetrating the first electrode and extending into or penetrating through the piezoelectric layer, and the second groove penetrating the second electrode and extending into or penetrating through the piezoelectric layer; and a reinforcement layer, disposed on at least one side of the first electrode or the second electrode at a bottom position of the groove.

Specifically, in the present embodiment, the first substrate includes a base 300 and a support layer 205 disposed on the base 300. The support layer 205 is bonded on the base 300, and the support layer 205 encloses a first cavity 200, and the first cavity 200 exposes an upper surface of the base 300. In the present embodiment, the first cavity 200 is an annular closed cavity, and the first cavity 200 can be formed by etching the support layer 205 through an etching process. However, a technology of the present disclosure is not limited only to the above structure. In another embodiment, the first substrate is a single-layer structure, and the first cavity is disposed in the first substrate. In the present embodiment, the support layer 205 is combined with the base 300 by a bonding method including a covalent bonding, an adhesive bonding, or a fusion bonding. In the present embodiment, the support layer 205 and the base 300 are bonded through a bonding layer. A material of the bonding layer includes silicon oxide, silicon nitride, silicon oxynitride, silicon carbonitride or ethyl silicate.

In the present embodiment, a material of the base 300 may be at least one of the following materials: silicon (Si), germanium (Ge), silicon germanium (SiGe), silicon carbon (SiC), silicon germanium carbon (SiGeC)), indium arsenide (InAs), gallium arsenide (GaAs), indium phosphide (InP) or other III/V compound semiconductors. The material of the base 300 can be a multilayer structure composed of the above semiconductors and can also be a ceramic substrate such as alumina, a quartz, a glass substrate, or the like. A material of the support layer 205 can be any suitable dielectric material, including but not limited to one of silicon oxide, silicon nitride, silicon oxynitride, silicon carbonitride and other materials.

In the present embodiment, a shape of the bottom surface of the first cavity 200 is a rectangle. But in other embodiments of the present disclosure, the shape of the bottom surface of the first cavity 200 may also be a circle, an ellipse, or a polygon other than a rectangle such as pentagon, hexagon, or the like. A piezoelectric stack structure is disposed above the first cavity 200. The piezoelectric stack structure includes a second electrode 203, a piezoelectric layer 202 and a first electrode 201 which are sequentially stack from bottom to top. The second electrode 203 is on the support layer 205, the piezoelectric layer 202 is on the second electrode 203, and the first electrode 201 is on the piezoelectric layer 202. A material of the second electrode 203 and the first electrode 201 can be any suitable conductive material or semiconductor material known to a person skilled in the art. The conductive material may be a metal material with conductive properties. For example, the conductive material may be made of one of molybdenum (Mo), aluminum (Al), copper (Cu), tungsten (W), tantalum (Ta), platinum (Pt), ruthenium (Ru), rhodium (Rh), iridium (Ir), chromium (Cr), titanium (Ti), gold (Au), osmium (Os), rhenium (Re), palladium (Pd) and the like or a laminate formed of the above metals. A semiconductor material is Si, Ge, SiGe, SiC, SiGeC, or the like. The second electrode 203 and the first electrode 201 may be formed by physical vapor deposition such as magnetron sputtering, evaporation, or chemical vapor deposition. The piezoelectric layer 202 can be made of aluminum nitride (AlN), zinc oxide (ZnO), lead zirconate titanate (PZT), lithium niobate, quartz, potassium niobate, lithium tantalate, or the like which has a wurtzite crystal structure such as aluminum nitride (AlN), lithium tantalate, or a combination thereof. When the piezoelectric layer 202 includes aluminum nitride (AlN), the piezoelectric layer 202 may further include a rare earth metal such as at least one of scandium (Sc), erbium (Er), yttrium (Y), and lanthanum (La). In addition, when the piezoelectric layer 202 includes aluminum nitride (AlN), the piezoelectric layer 202 may further include transition metals such as at least one of zirconium (Zr), titanium (Ti), manganese (Mn), and hafnium (Hf). The piezoelectric layer 202 may be deposited using any suitable method known to a person skilled in the art, such as chemical vapor deposition, physical vapor deposition, or atomic layer deposition.

A groove in the present embodiment includes a first groove 41 and a second groove 40. The first groove 41 penetrates through the first electrode 201 and the piezoelectric layer 202. The second groove 40 penetrates through the second electrode 203 and the piezoelectric layer 202. In the present embodiment, Inner sidewalls of the groove constitutes at least part of a boundary of an effective resonance area. The first electrode 201, the piezoelectric layer 202 and the second electrode 203 in the effective resonance area are stack on each other in a direction perpendicular to a surface of the piezoelectric layer 202. In the present embodiment, the first reinforcement layer 204 is disposed on the second electrode 203 at a bottom of the first groove 41. The second reinforcement layer 102 is disposed on the first electrode 201 at a bottom of the second groove 40. In the present embodiment, the first reinforcement layer 204 is disposed on a surface of the second electrode close to the first cavity 200. The second reinforcement layer 102 is disposed on a surface of the first electrode 201 away from the first cavity 200. In other embodiments, the first reinforcement layer may also be disposed on a surface of the second electrode away from the first cavity. The first reinforcement layer may also be disposed on upper and lower surfaces of the first electrode. Similarly, the second reinforcement layer may be disposed on any surface of the first electrode or on upper and lower surfaces of the first electrode. The first groove 41 and/or the second groove 40 make end faces of the electrodes and end faces of the piezoelectric layer in contact with the air, so that an acoustic impedance of an area where the groove is located is mismatched, which prevents leakage of a transverse wave in the effective region and improves a Q value of the resonator. The reinforcement layer can reinforce the electrodes in a groove area and prevent breakage of a film-like electrode.

A material of the reinforcement layer includes a conductive material or a dielectric material. When the material of the reinforcement layer is a conductive material, in a preferred solution, a material of the first reinforcement layer is same as a material of the second electrode, and a material of the second reinforcement layer is same as a material of the first electrode. The dielectric material includes silicon oxide, silicon nitride, silicon oxynitride, silicon carbonitride, or the like.

In the present embodiment, an area enclosed by inner sidewalls of the first groove 41 and the second groove 40 is the effective resonance area. Projections of the inner sidewalls of the first groove 41 and the second groove 40 in a surface direction of the piezoelectric layer are a closed pattern. The pattern is an irregular polygon. The first electrode 210, the piezoelectric layer 202, and the second electrode 203 in the effective resonance area are stack on each other in a direction perpendicular to a surface of the piezoelectric layer. In a typical example, the first groove 41 and the second groove 40 are both continuous structures and are disposed opposite to each other. Projections of two ends of the first groove 41 and the second groove 40 are in contact with each other. The first groove and/or the second groove may be discontinuous structures. Projections of the first groove 41 and the second groove 40 are complementary to form a closed pattern. In another embodiment, the groove includes the first groove 41 and the second groove 40, and the inner sidewalls of the first groove 41 and the second groove 40 only constitute a part of the boundary of the effective resonance area.

In another embodiment, the first groove and/or the second groove extend to a partial depth in the piezoelectric layer without penetrating through the piezoelectric layer. In other embodiments, the groove may include only the first groove or the second groove. When the groove includes only the first groove, the first reinforcement layer is disposed at a bottom of the first groove and at a corresponding position of the second electrode 203. When the groove only includes the second groove, a second reinforcement layer is provided at the bottom of the second groove and at a corresponding position of the first electrode 201.

In the present embodiment, a projection of the bottom of the first groove 41 in the surface direction of the piezoelectric layer 202 is within a projection range of the first reinforcement layer 204 in the surface direction of the piezoelectric layer 202. A projection of the bottom of the second groove 40 in the surface direction of the piezoelectric layer 202 is within a projection range of the second reinforcement layer 102 in the surface direction of the piezoelectric layer 202. That is, the reinforcement layer completely covers a bottom area of the groove, and the reinforcement layer located outside the groove and at a boundary of the effective resonance area can not only improve structural strengths of the electrodes, but also form an acoustic impedance mismatched area in the effective resonance area to prevent lateral leakage of an acoustic wave and improve quality factor of the resonator.

### Exemplary Embodiment 2

A difference between the present embodiment and exemplary Embodiment 1 is that protrusions are disposed at a boundary of the effective resonance area. The protrusions are disposed opposite to the reinforcement layer. Other structures of exemplary Embodiment 2 are same as or similar to other structures of exemplary Embodiment 1.

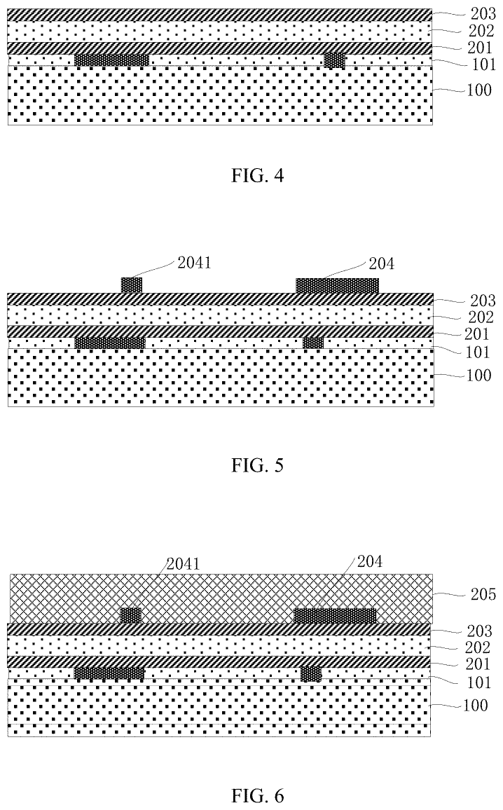

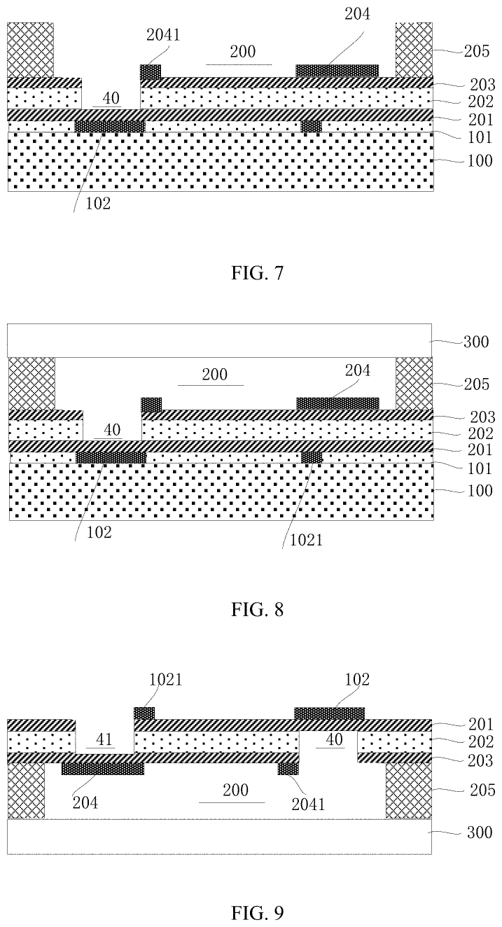

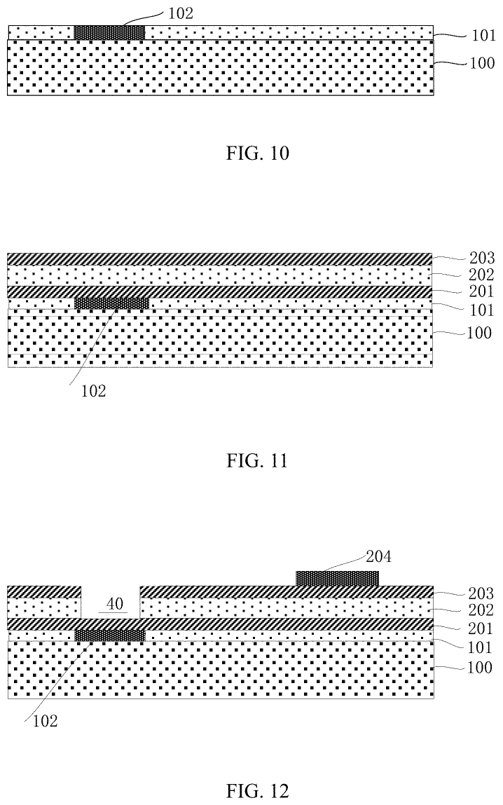

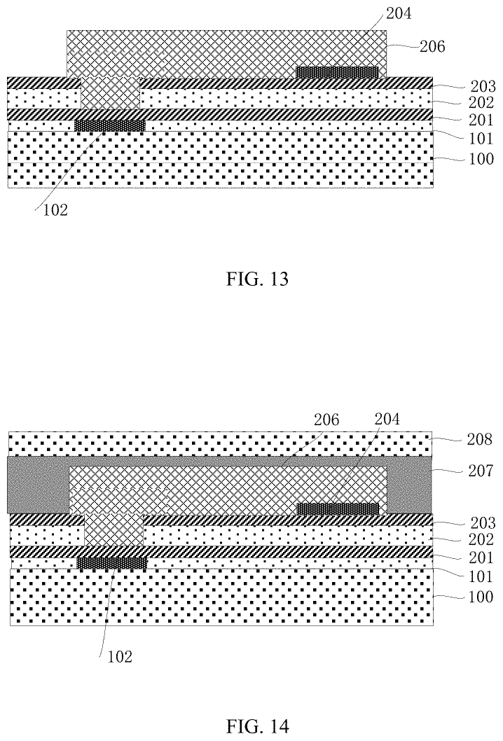

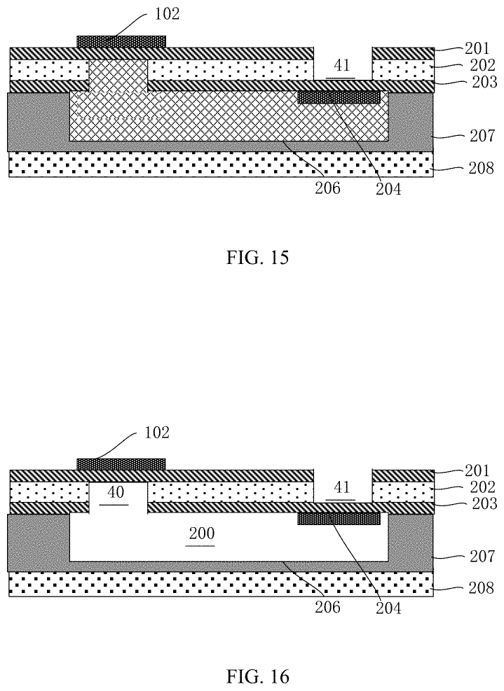

Referring to FIG. 2, specifically, in the present embodiment, the protrusions include a first protrusion and a second protrusion. A second protrusion 2041 is disposed on a horizontally opposite side of the first reinforcement layer 204 and in an area where inner sidewalls of the second groove 40 are located. A first protrusion 1021 is disposed on a horizontally opposite side of the second reinforcement layer 102 in an area where inner sidewalls of the first groove 41 are located. In the present embodiment, the first protrusion 1021 and the second reinforcement layer are made of a same material, have a same thickness, and are formed in a simultaneous process. The second protrusion 2041 and the first reinforcement layer 204 are made of a same material, have a same thickness, and are formed in a simultaneous process. In other embodiments, materials and heights of the protrusions and the reinforcement layers may also be different. Disposing the protrusions at the boundary of the effective resonance area can make areas where the protrusions are located and the effective resonance area to achieve an impedance mismatch, prevent leakage of a transverse wave in the effective resonance area, and improve the Q value of the resonator. In an alternative solution, projections of the first protrusion 1021 and the second reinforcement layer 102 in the surface direction of the piezoelectric layer constitute a closed pattern and/or projections of the second protrusion 2041 and the first reinforcement layer 204 in the surface direction of the piezoelectric layer constitute a closed pattern.

The first protrusion 1021 is disposed opposite to the second reinforcement layer 102 in a horizontal direction to form a complete or nearly complete ring shape, and the second protrusion 2041 is disposed opposite to the first reinforcement layer 204 in the horizontal direction. The above arrangement increases an impedance mismatch area (boundaries of the effective resonance areas all form impedance mismatch areas). In a vertical direction, the first protrusion 1021 and the first reinforcement layer 204 have an opposite area, and in the vertical direction, the second protrusion 2041 and the second reinforcement layer 102 have an opposite area. The above arrangement can further increase degree of impedance mismatch, and the above arrangement can prevent lateral leakage of an acoustic wave to a large extent and improve quality factor of the resonator.

An embodiment of the present disclosure provides a filter, including at least one thin film bulk acoustic resonator in exemplary Embodiment 1 and/or Embodiment 2.

### Exemplary Embodiment 3

Exemplary Embodiment 3 provides a forming method of a thin-film bulk acoustic resonator, including following exemplary steps.

S01: provide a carrier substrate.

S02: form a first electrode, a piezoelectric layer and a second electrode in sequence on the carrier substrate.

S03: form a first substrate with a first cavity on the second electrode.

S04: remove the carrier substrate.

S05: the thin film bulk acoustic resonator includes a second groove and a second reinforcement layer. Forming the second groove and the second reinforcement layer includes: before forming the first electrode, forming the second reinforcement layer on the carrier substrate; and after forming the second electrode, forming the second groove penetrating through the second electrode over an area of the second reinforcement layer and extending into or penetrating through the piezoelectric layer. And/or, the thin-film bulk acoustic resonator includes a first groove and a first reinforcement layer. Forming the first groove and the first reinforcement layer includes: after forming the second electrode, forming the first reinforcement layer on the second electrode; and after removing the carrier substrate, forming the first groove penetrating through the first electrode over a region of the first reinforcement layer and extending into or penetrating through the piezoelectric layer.

As described herein, the Step S0N (S01, S02, S03 . . . ) does not represent or indicate any order.

FIGS. 3-9 illustrate schematic diagrams of structures corresponding to different stages for forming a thin-film piezoelectric acoustic resonator provided by exemplary Embodiment 3 of the present disclosure. FIGS. 3-9 are referred for a detailed description of each exemplary step.

Referring to FIG. 3, step S01 is performed to provide a carrier substrate 100.

The carrier substrate 100 may be made of at least one of following materials: silicon (Si), germanium (Ge), silicon germanium (SiGe), silicon carbon (SiC), silicon germanium carbon (SiGeC), indium arsenide (InAs), gallium arsenide (GaAs), indium phosphide (InP) or another III/V compound semiconductor. The carrier substrate 100 may also be made of a ceramic substrate such as an alumina, a quartz or glass substrate, or the like.

In the present embodiment, the thin film bulk acoustic resonator includes not only the first groove and the first reinforcement layer, but also the second groove and the second reinforcement layer. Inner sidewalls of the first groove and/or the second groove constitute at least part of a boundary of an effective resonance area. The first electrode, the piezoelectric layer and the second electrode in the effective resonance area are stack on each other in a direction perpendicular to the surface of the piezoelectric layer. After step S01 is performed, step S05 is performed to form the second reinforcement layer. Specifically, referring to FIG. 3, a second reinforcement material layer is formed on the carrier substrate 100, and a first reinforcement material layer is patterned to form the second reinforcement layer 102. On the carrier substrate 100, a second dielectric layer 101 is formed on a periphery of the second reinforcement layer, so that a surface of the second dielectric layer 101 is flush with a surface of the second reinforcement layer 102. Referring to exemplary Embodiment 1, a material of the second reinforcement layer can be formed by a deposition method to form the second reinforcement material layer. The second dielectric layer needs to be removed in a later process. A material of the second dielectric layer is selected from an easily removable material, such as low temperature silicon dioxide, polyimide, amorphous carbon, or germanium. A structural form and function of the first groove and the first reinforcement layer can be referred to exemplary Embodiment 1.

In the present embodiment, the thin film bulk acoustic wave resonator further includes a first protrusion 1021 disposed opposite to the second reinforcement layer 102 in the horizontal direction. A positional relationship between the first protrusion 1021 and the second reinforcement layer 102 refers to the exemplary Embodiment 2. In the present embodiment, the first protrusion 1021 and the second reinforcement layer 102 are formed simultaneously. Forming the first protrusion 1021 includes: forming a reinforcing material layer; and patterning the reinforcing material layer to form the second reinforcing layer 102 and the first protrusion 1021. Materials and heights of the first protrusion and the reinforcement layer are same. In other embodiments, the first protrusion and the second reinforcement layer may also be formed separately. Materials or heights of the first protrusion and the reinforcement layer may be same or different. Structures, positional relationship and function of the protrusions and the reinforcement layers can be referred to relevant descriptions of exemplary Embodiment 1 and Embodiment 2.

Referring to FIG. 4, step S02 is performed. The first electrode 201, the piezoelectric layer 202 and the second electrode 203 are sequentially formed on the second dielectric layer. Materials and forming methods of the first electrode 201, the piezoelectric layer 202 and the second electrode 203 are in accordance with Embodiment 1, which are not repeated herein.

Referring to FIG. 5, step S05 is performed to form the first reinforcement layer 204. The first reinforcement material layer is formed on a surface of the second electrode 203 through a deposition process. The first reinforcement material layer is patterned to form the first reinforcement layer 204. In the present embodiment, the thin-film bulk acoustic wave resonator further includes a second protrusion 2041 disposed opposite to the first reinforcement layer 204 in the horizontal direction. A positional relationship between the second protrusion 2041 and the first reinforcement layer 204 is referred to Embodiment 2. In the present embodiment, the second protrusion 2041 are formed simultaneously with the first reinforcement layer 204. Forming the second protrusion 2041 includes: forming a reinforcement material layer; and patterning the reinforcement material layer to form the first reinforcement layer 204 and the second protrusion 2041. Materials and heights of the second protrusion and the first reinforcement layer are same. In other embodiments, the second protrusion and the first reinforcement layer may also be formed separately. Materials and heights of the second protrusion and the first reinforcement layer may be same or different.

Referring to FIGS. 6-8, step S03 is performed to form a first substrate with a first cavity 200 on the second electrode 203. Referring to FIG. 6, a support layer 205 is formed by physical vapor deposition or chemical vapor deposition, covering the second electrode 203, the first reinforcement layer 204 and the second protrusion 2041. A material of the support layer 205 may be any suitable dielectric material, including but not limited to at least one of silicon oxide, silicon nitride, silicon oxynitride, silicon carbonitride and other materials. Referring to FIG. 7, the support layer 205 is patterned to form the first cavity 200. In the present embodiment, the first cavity 200 penetrates through the support layer 205. The first cavity 200 exposes the first reinforcement layer 204 and the second protrusion 2041. A structure of the first cavity 200 refers to Embodiment 1. In the present embodiment, after the second electrode 203 is formed, a second groove 40 penetrating through the second electrode 203 and the piezoelectric layer 202 is formed above the region of the second reinforcement layer 102. A projection of the bottom of the second groove 40 in the direction of the surface of the piezoelectric layer 202 is made to be within a projection range of the second reinforcement layer 102 in the direction of the surface of the piezoelectric layer 202. It should be noted that, the second groove may be formed before the support layer 205 is formed or may be formed after the first cavity 200 is formed. In the present embodiment, the second groove 40 is formed on a side of the second protrusion 2041 away from the effective resonance area. The second protrusion 2041 and the second reinforcement layer 102 are provided with an overlapping area in the direction perpendicular to the surface of the piezoelectric layer. The overlapping area has a stronger impedance mismatch effect.

Referring to FIG. 8, a base 300 is provided. The base 300 is bonded on the support layer 205 to cover the first cavity 200. The first substrate includes the support layer 205 and the base 300. A material of the base 300 and a bonding method between the base 300 and the support layer 205 can be referred to Embodiment 1, which are not repeated herein.

Referring to FIG. 9, step S04 is performed to remove the carrier substrate 100. The carrier substrate 100 may be removed by grinding, wet etching or etching. The embodiment further includes removing the second dielectric layer 101.

### Exemplary Embodiment 4

FIGS. 10-16 illustrates a schematic diagram of structures corresponding to different stages for forming a thin-film bulk acoustic resonator according to exemplary Embodiment 4. Each exemplary step will be described in detail with reference to FIGS. 10-16.

Referring to FIG. 10, a carrier substrate 100 is provided, and a material of the carrier substrate 100 refers to Embodiment 3. A second reinforcement layer 102 and a second dielectric layer 101 around a periphery of the second reinforcement layer are formed on the carrier substrate 100. For materials and forming methods of the second dielectric layer 101 and the second reinforcement layer 102, references can be made to the exemplary Embodiment 3.

Referring to FIG. 11, the first electrode 201, the piezoelectric layer 202 and the second electrode 203 are sequentially formed on the second dielectric layer 101 and the second reinforcement layer 102. Materials and forming methods of the first electrode 201, the piezoelectric layer 202 and the second electrode 203 are in accordance with Embodiment 1, which are not repeated herein.

Referring to FIG. 12, the first reinforcement layer 204 is formed on the surface of the second electrode 203. A material and a forming method of the first reinforcement layer can be referred to Embodiment 3, which are not repeated herein. The second groove 40 is formed above the first reinforcement layer 102. The second groove 40 penetrates the second electrode 203 and the piezoelectric layer 202. The second groove 40 may only penetrate part of a thickness of the piezoelectric layer 202. A structure of the second groove 40 refers to Embodiment 1.

Referring to FIGS. 13-16, a first substrate with a first cavity is formed on the second electrode 203. Specifically, a sacrificial layer 206 is formed on the second electrode 203, a first substrate is formed to cover the sacrificial layer 206 and a periphery of the sacrificial layer 206, and the sacrificial layer 206 is removed to form the first void cavity 200.

Specifically, referring to FIG. 13, a sacrificial material layer is formed on the surface of the second electrode 203, the sacrificial material layer is patterned, and the sacrificial layer 206 is formed. The sacrificial layer 206 covers an area enclosed by the first reinforcement layer 204 and the second reinforcement layer 102 and fills the second groove. A material of the sacrificial material layer includes phosphosilicate glass, low temperature silicon dioxide, borophosphosilicate glass, germanium, carbon, polyimide, or photoresist. The sacrificial material layer can be formed by a deposition process or a spin coating process depending on a material.

Referring to FIG. 14, a dielectric layer 207 is formed to cover the second sacrificial layer 206 and a periphery of the second sacrificial layer. The dielectric layer 207 encapsulates the second sacrificial layer 206. A material of the dielectric layer 207 includes silicon oxide, silicon nitride, silicon oxynitride and other materials. The dielectric layer 207 can be formed by a deposition method. A dielectric layer can be used as a first substrate. In the embodiment, a substrate 208 is formed on an upper surface of the dielectric layer 207. The substrate 208 can be bonded on the upper surface of the dielectric layer 207 through a bonding process. A purpose of bonding the substrate 208 is to shorten a deposition time of the dielectric layer because a certain thickness is required above the surface of the sacrificial layer 206 to improve a structural strength of the first substrate. It is relatively slow to form the dielectric layer 207 with a certain thickness by deposition, and a process time is shortened by bonding the substrate 208.

Referring to FIG. 15, the carrier substrate 100 is removed. The carrier substrate 100 may be removed by grinding, wet etching or etching. The embodiment also includes removing the second dielectric layer 101. After the carrier substrate 100 is removed, a first groove 41 is formed above the first reinforcement layer 204. The first groove 41 penetrates through the first electrode 201 and the piezoelectric layer 202. The first groove 41 may only penetrate part of a thickness of the piezoelectric layer 202. A structure of the first groove 41 refers to Embodiment 1.

Referring to FIG. 16, the sacrificial layer is removed to form a first cavity 200, which may be above the first cavity. Outsides of the first reinforcement layer and the second reinforcement layer form release holes penetrating the first electrode 201, the piezoelectric layer 202 and the second electrode 203. The sacrificial layer is removed through release holes. According to a selected sacrificial layer material, a corresponding removal method is adopted. For example, when the sacrificial layer material is polyimide or photoresist, the sacrificial layer can be removed by an ashing method. The ashing method is specifically that at a temperature of 250 degrees Celsius, through a chemical reaction between oxygen in the release holes and the sacrificial layer material, generated gaseous substances are volatilized. When the sacrificial layer material is low-temperature silicon dioxide, the sacrificial layer is removed by a reaction between hydrofluoric acid solvent and low-temperature silicon dioxide.

In the embodiment, both the first groove and the first reinforcement layer and the second groove and the second reinforcement layer are formed. According to a method of the embodiment, only one of the first groove and the second groove and a corresponding reinforcement layer may be formed. In the embodiment, the first protrusion and the second protrusion are not formed. It should be understood that the first protrusion and the second protrusion may also be formed by using the method of the embodiment. Positions and methods of forming the first protrusion and the second protrusion can be referred to Embodiment 3.

It should be noted that each embodiment in the present specification is described in a related manner. Same and similar parts between various embodiments may be referred to each other. Each embodiment highlights differences from the other embodiments. Especially, since a method embodiment is basically like a structural embodiment, a description of the method embodiment is relatively simple. Especially for Embodiment 4, a material of a same structure, a positional relationship and related parts of a forming method can be referred to a description of Example 3.

As disclosed, the technical solutions of the present disclosure have the following beneficial effects. A groove is disposed on a piezoelectric stack structure, and a first electrode or a second electrode and an end face of a piezoelectric layer exposed in the groove form an acoustic impedance mismatch area with gas in the groove, which can effectively prevent lateral leakage of an acoustic wave and improve quality factor of a resonator. A reinforcement layer is disposed at a bottom of the groove, and the reinforcement layer can reinforce electrodes in the groove area and prevent a film-shaped electrode from being damaged. Further, a reinforcement layer located outside the groove and at a boundary of an effective resonance area can not only improve structural strengths of the electrodes, but also form an acoustic impedance mismatch area, to prevent lateral leakage of an acoustic wave and improve quality factor of the resonator. Further, a projection of the groove in a surface direction of a first substrate is an annular shape, and an inside of the annular shape is an effective resonance area of the resonator. The above arrangement can greatly increase the acoustic impedance mismatch area and further improve the quality factor of the resonator. Further, the groove includes a first groove and a second groove. Protrusions are disposed along an inner boundary of the groove and surfaces of the first electrode and the second electrode. The protrusions are disposed opposite the reinforcement layer in a horizontal direction to form a complete or nearly complete ring to increase the impedance mismatch area (boundaries of effective resonance areas all form the impedance mismatch area). In a vertical direction, there is an opposite area between the protrusions and the reinforcement layer, which can further increase degree of impedance mismatch. The above arrangement can prevent lateral leakage of an acoustic wave to a large extent and improve quality factor of the resonator.

The above description is only a description of the preferred embodiments of the present disclosure and is not intended to limit the scope of the present disclosure. Any changes and modifications made by a person skilled in the art according to the above disclosure fall within the protection scope of the claims.

What is claimed is:

1. A thin-film bulk acoustic resonator, comprising:
a first substrate, an upper surface of the first substrate being provided with a first cavity;
a piezoelectric stack structure, disposed on the upper surface of the first substrate and covering the first cavity, the piezoelectric stack structure including a second electrode, a piezoelectric layer and a first electrode which are stacked sequentially from bottom to top;
a groove, including a first groove and/or a second groove, the first groove penetrating through the first electrode and extending into or penetrating through the piezoelectric layer, and the second groove penetrating through the second electrode and extending into or penetrating through the piezoelectric layer; and
a reinforcement layer, disposed on at least one side of the first electrode or the second electrode at a bottom of the groove.

2. The thin-film bulk acoustic resonator according to claim 1, further comprising a first groove and a second groove, and an area surrounded by inner sidewalls of the first groove and the second groove being an effective resonance area.

3. The thin-film bulk acoustic resonator according to claim 1, wherein the reinforcement layer is disposed on a side surface of the first electrode or the second electrode at bottoms of the groove away from the bottoms of the groove.

4. The thin-film bulk acoustic resonator according to claim 1, wherein a projection of the bottoms of the groove in a direction of a surface of the piezoelectric layer is within a projection range of the reinforcement layer in the direction of the surface of the piezoelectric layer.

5. The thin-film bulk acoustic resonator according to claim 1, wherein a material of the reinforcement layer includes a conductive material or a dielectric material.

6. The thin-film bulk acoustic resonator according to claim 1, wherein protrusions are disposed at a boundary of the effective resonance area, and the protrusions are disposed opposite to the reinforcement layer.

7. The thin-film bulk acoustic resonator according to claim 6, wherein a material of the protrusions is same as a material of the reinforcement layer.

8. The thin-film bulk acoustic resonator according to claim 6, wherein heights of the protrusions are same as a height of the reinforcement layer.

9. A filter comprising a thin-film bulk acoustic resonator comprising:
a first substrate, an upper surface of the first substrate being provided with a first cavity;
a piezoelectric stack structure, disposed on the upper surface of the first substrate and covering the first cavity, the piezoelectric stack structure including a second electrode, a piezoelectric layer and a first electrode which are sequentially stack from bottom to top;
a groove, including a first groove and/or a second groove, the first groove penetrating through the first electrode and extending into or penetrating through the piezoelectric layer, and the second groove penetrating through the second electrode and extending into or penetrating through the piezoelectric layer; and
a reinforcement layer, disposed on at least one side of the first electrode or the second electrode at a bottom of the groove.

10. A method of forming a thin-film bulk acoustic resonator, comprising:
providing a carrier substrate;
forming a first electrode, a piezoelectric layer and a second electrode sequentially on the carrier substrate;
forming a first substrate with a first cavity on the second electrode; and
removing the carrier substrate:
wherein the thin film bulk acoustic wave resonator includes a second groove and a second reinforcement layer, and forming the second groove and the second reinforcement layer includes: before forming the first electrode, forming the second reinforcement layer on the carrier substrate; after forming the second electrode, forming the second groove penetrating through the second electrode over a region of the second reinforcement layer, and extending into or through the piezoelectric layer, and/or,
the thin-film bulk acoustic wave resonator includes a first groove and a first reinforcement layer, and forming the first groove and the first reinforcement layer includes: after forming the second electrode, forming the first reinforcement layer on the second electrode; after removing the carrier substrate, forming the first groove penetrating through the first electrode over a region of the first reinforcement layer, and extending into or penetrating through the piezoelectric layer.

11. The method according to claim 10, the forming the second reinforcement layer on the carrier substrate comprising:
forming a second reinforcement material layer on the carrier substrate, patterning the first reinforcement material layer to form the second reinforcement layer, and on the carrier substrate, forming a second dielectric layer at a periphery of the second reinforcement layer, so that a surface of the second dielectric layer is flush with a surface of the second reinforcement layer; and
removing the second dielectric layer after removing the carrier substrate.

12. The method according to claim 10, the forming the first reinforcement layer on the second electrode comprising:
forming a first reinforcement material layer on a surface of the second electrode through a deposition process and patterning the first reinforcement material layer to form the first reinforcement layer.

13. The method according to claim 10, the forming the second groove comprising:
after forming the second electrode, forming the second groove penetrating through the second electrode and the piezoelectric layer over a region of the second reinforcement layer, and making a projection of a bottom of the second groove in a surface direction of the piezoelectric layer within a projection range of the second reinforcement layer in the surface direction of the piezoelectric layer.

14. The method according to claim 10, the forming the first groove comprising:
after forming the carrier substrate, forming the first groove penetrating through the first electrode and the piezoelectric layer over the region of the first reinforcement layer, and making a projection of the bottom of the first groove in a surface direction of the piezoelectric layer within a projection range of the first reinforcement layer in the surface direction of the piezoelectric layer.

15. The method according to claim 10, forming the first substrate with the first cavity comprising:
forming a support layer covering the second electrode; patterning the support layer to form the first cavity; and providing a base, bonding the base on the support layer, covering the first cavity, the first substrate including the support layer and the base; or
forming a sacrificial layer on the second electrode; forming a first substrate covering the sacrificial layer and a periphery of the sacrificial layer; and removing the sacrificial layer to form the first cavity.

16. The method according to claim 10, wherein the thin film bulk acoustic wave resonator includes a first groove and a second groove, and an area surrounded by inner sidewalls of the first groove and the second groove is an effective resonance area.

17. The method according to claim 10, wherein the thin film bulk acoustic wave resonator includes a second groove and a second reinforcement layer, the method further includes forming a first protrusion at a boundary of the effective resonance area, the first protrusion protrudes from a surface of the first electrode, the first protrusion is disposed opposite to the second reinforcement layer, the first protrusion and the second reinforcement layer are formed at a same time, and forming the first protrusion includes forming a reinforcement material layer, and patterning the reinforcement material layer to form the second reinforcement layer and the first protrusion.

18. The method according to claim 10, wherein the thin-film bulk acoustic wave resonator includes a first groove and a first reinforcement layer, and the method further includes forming a second protrusion at a boundary of the effective resonance area, the second protrusion protrudes from a surface of the second electrode, the second protrusion is disposed opposite to the first reinforcement layer, the second protrusion and the first reinforcement layer are formed at a same time, and forming the second protrusion includes forming a reinforcement material layer, and patterning the reinforcement material layer to form the first reinforcement layer and the second protrusion.
